(19) United States
(12) Patent Application Publication
(10) Pub. No.: US 2025/0226210 A1
(43) Pub. Date: Jul. 10, 2025

(54) FILM FORMATION METHOD AND SUBSTRATE PROCESSING APPARATUS

(71) Applicant: Tokyo Electron Limited, Tokyo (JP)

(72) Inventors: Hiroki MURAKAMI, Nirasaki City (JP); Shuichiro SAKAI, Nirasaki City (JP); Hisashi HIGUCHI, Nirasaki City (JP); Kazuki YAMADA, Nirasaki City (JP)

(21) Appl. No.: 19/093,805

(22) Filed: Mar. 28, 2025

Related U.S. Application Data
(63) Continuation of application No. PCT/JP2023/033961, filed on Sep. 19, 2023.

(30) Foreign Application Priority Data
Sep. 28, 2022 (JP) 2022-155500

(51) Int. Cl. H01L 21/02; C23C 8/20; C23C 8/24; C23C 8/80; C23C 16/04; C23C 16/40; C23C 16/52; C23C 16/56; C23C 28/04; H01J 37/32

(52) U.S. Cl. CPC H01L 21/02312; C23C 8/20; C23C 8/24; C23C 8/80; C23C 16/04; C23C 16/401; C23C 16/52; C23C 16/56; C23C 28/04; H01L 21/02164; H01J 37/3244; H01J 2237/332; H01J 2237/3387

(57) ABSTRACT

A film formation method of forming, in a substrate having a first surface and a second surface, a film containing at least silicon and oxygen on the second surface in a selective manner with respect to the first surface, the film formation method includes: causing the first surface to be a nitrided surface made of nitride or a carbonized surface made of carbide by supplying a nitrogen-containing gas or a carbon-containing gas to the substrate; supplying a metal-containing catalyst to the substrate; and supplying a silicon precursor including silanol to the substrate.

### CROSS-REFERENCE TO RELATED APPLICATION

This application is a Bypass Continuation application of PCT International Application No. PCT/JP2023/033961, filed on Sep. 19, 2023 and designating the United States, the international application being based upon and claiming the benefit of priority from Japanese Patent Application No. 2022-155500, filed on Sep. 28, 2022, the entire contents of which are incorporated herein by reference.

### TECHNICAL FIELD

The present disclosure relates to a film formation method and a substrate processing apparatus.

### BACKGROUND

In Patent Document 1, a method of forming a silica layer on a substrate is disclosed. This method includes exposing a heated substrate, including a region containing a metal or semimetal compound having Lewis acid property, to silanol vapor, thereby forming a silica layer having a thickness exceeding 2 nm on an acidic region of the substrate.

In Patent Document 2, a method for depositing a thin film of silicon dioxide on a substrate in a reactant chamber by atomic layer deposition is disclosed. This method includes supplying a gas-phase reactant pulse including a metal precursor into the reactant chamber to form only a substantially single molecular layer of the metal precursor on the substrate, removing excess reactants from the reactant chamber if necessary, supplying a gas-phase reactant pulse including a silicon precursor into the reactant chamber to react the silicon precursor with the metal precursor on the substrate, and removing excess reactants and any reaction by-products from the reactant chamber. A temperature of the substrate is less than approximately 150 degrees C.

### PRIOR ART DOCUMENTS

### Patent Documents

Patent Document 1: Japanese Patent Laid-open Publication No. 2005-521792
Patent Document 2: Japanese Patent Laid-open Publication No. 2010-010686

### SUMMARY

According to an embodiment of the present disclosure, a film formation method of forming, in a substrate having a first surface and a second surface, a film containing at least silicon and oxygen on the second surface in a selective manner with respect to the first surface includes: causing the first surface to be a nitrided surface made of nitride or a carbonized surface made of carbide by supplying a nitrogen-containing gas or a carbon-containing gas to the substrate; supplying a metal-containing catalyst to the substrate; and supplying a silicon precursor including silanol to the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating a configuration example of a substrate processing apparatus according to the present embodiment.

FIG. 2 is a time chart illustrating an example of a film formation process according to the present embodiment.

FIG. 3 is a time chart illustrating another example of a film formation process according to the present embodiment.

FIG. 4 illustrates an example of a graph illustrating results of an average film thickness in film formation processes.

FIG. 5 illustrate an example of a graph illustrating results of an average film thickness in film formation processes.

FIG. 6A is a schematic diagram illustrating an example of selective growth of a silicon oxide film on a planar surface.

FIG. 6B is a schematic diagram illustrating an example of selective growth of a silicon oxide film on a planar surface.

FIG. 6C is a schematic diagram illustrating an example of selective growth of a silicon oxide film on a planar surface.

FIG. 6D is a schematic diagram illustrating an example of selective growth of a silicon oxide film on a planar surface.

FIG. 6E is a schematic diagram illustrating an example of selective growth of a silicon oxide film on a planar surface.

FIG. 7A is a schematic diagram illustrating another example of selective growth of a silicon oxide film on a planar surface.

FIG. 7B is a schematic diagram illustrating another example of selective growth of a silicon oxide film on a planar surface.

FIG. 7C is a schematic diagram illustrating another example of selective growth of a silicon oxide film on a planar surface.

FIG. 7D is a schematic diagram illustrating another example of selective growth of a silicon oxide film on a planar surface.

FIG. 7E is a schematic diagram illustrating another example of selective growth of a silicon oxide film on a planar surface.

FIG. 8A is a schematic diagram illustrating another example of selective growth of a silicon oxide film on a planar surface.

FIG. 8B is a schematic diagram illustrating another example of selective growth of a silicon oxide film on a planar surface.

FIG. 8C is a schematic diagram illustrating another example of selective growth of a silicon oxide film on a planar surface.

FIG. 8D is a schematic diagram illustrating another example of selective growth of a silicon oxide film on a planar surface.

FIG. 8E is a schematic diagram illustrating another example of selective growth of a silicon oxide film on a planar surface.

FIG. 9A is a schematic diagram illustrating an example of selective growth of a silicon oxide film in a three-dimensional shape.

FIG. 9B is a schematic diagram illustrating another example of selective growth of a silicon oxide film in a three-dimensional shape.

FIG. 9C is a schematic diagram illustrating another example of selective growth of a silicon oxide film in a three-dimensional shape.

FIG. 10A is a schematic diagram illustrating another example of selective growth of a silicon oxide film in a three-dimensional shape.

FIG. 10B is a schematic diagram illustrating another example of selective growth of a silicon oxide film in a three-dimensional shape.

FIG. 10C is a schematic diagram illustrating another example of selective growth of a silicon oxide film in a three-dimensional shape.

FIG. 11A is a schematic diagram illustrating another example of selective growth of a silicon oxide film in a three-dimensional shape.

FIG. 11B is a schematic diagram illustrating another example of selective growth of a silicon oxide film in a three-dimensional shape.

FIG. 11C is a schematic diagram illustrating another example of selective growth of a silicon oxide film in a three-dimensional shape.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for carrying out the present disclosure will be described with reference to the drawings. In each drawing, the same reference numerals may be given to the same components, and redundant descriptions may be omitted.

### <Substrate Processing Apparatus>

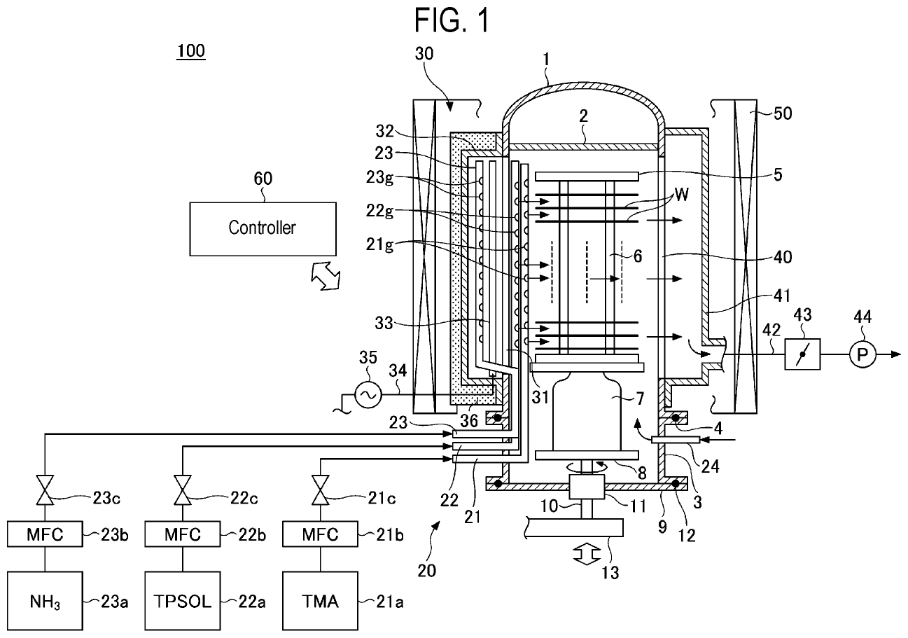

A substrate processing apparatus 100 according to the present embodiment will be described with reference to FIG. 1. FIG. 1 is a schematic diagram illustrating a configuration example of the substrate processing apparatus 100 according to the present embodiment.

The substrate processing apparatus 100 includes a cylindrical processing container 1 having a ceiling and an open bottom. The entire processing container 1 is made of, for example, quartz. A ceiling plate 2, which is made of quartz, is provided near a top inside the processing container 1, and a region under the ceiling plate 2 is sealed. A cylindrical molded metallic manifold 3 is connected to a bottom opening of the processing container 1 via a seal member 4 such as an O-ring.

The manifold 3 supports the bottom of the processing container 1, and a wafer boat 5, in which multiple (e.g., 25 to 150) semiconductor wafers (hereinafter referred to as “substrate W”) as substrates are placed in multiple stages, is inserted into the processing container 1 from below the manifold 3. In this way, the multiple substrates W are accommodated substantially horizontally inside the processing container 1 at intervals along a vertical direction. The wafer boat 5 is made of, for example, quartz. The wafer boat 5 includes three rods 6 (two are illustrated in FIG. 1), and the multiple substrates W are supported by grooves (not illustrated) formed in the rods 6.

The wafer boat 5 is placed on a table 8 with a heat reservoir 7, which is made of quartz, interposed therebetween. The table 8 is supported on a rotating shaft 10, which penetrates a metallic (stainless steel) lid 9 configured to open or close a bottom opening of the manifold 3.

A magnetic fluid seal 11 is provided around a penetrating portion of the rotating shaft 10 to airtightly seal and rotatably support the rotating shaft 10. A seal member 12 is provided between a peripheral portion of the lid 9 and the bottom of the manifold 3 to maintain airtightness inside the processing container 1.

The rotating shaft 10 is attached to a tip of an arm 13, which is supported, for example, by a lifting mechanism (not illustrated) such as a boat elevator, and the wafer boat 5 and the lid 9 are integrally moved up or down to thereby be inserted into or separated from the processing container 1. In addition, the table 8 may be fixed to the lid 9, which allows the substrate W to be processed without rotating the wafer boat 5.

Further, the substrate processing apparatus 100 includes a gas supplier 20 configured to supply predetermined gases such as a processing gas and a purge gas into the processing container 1.

The gas supplier 20 includes gas supply pipes 21 to 24. The gas supply pipes 21, 22, and 23 are made of, for example, quartz, and inwardly penetrate a sidewall of the manifold 3 and are then bent upward to extend vertically. A plurality of gas holes 21g, 22g, and 23g are formed at predetermined intervals in vertical portions of the gas supply pipes 21, 22, and 23 over a vertical length corresponding to a wafer supporting range of the wafer boat 5. The respective gas holes 21g, 22g, and 23g discharge gases in the horizontal direction. The gas supply pipe 24 is made of, for example, quartz, and is formed as a short quartz pipe provided to penetrate the sidewall of the manifold 3.

The vertical portion (vertical portion where the gas holes 21g are formed) of the gas supply pipe (metal-containing catalyst supplier) 21 is located inside the processing container 1. A metal-containing catalyst gas is supplied to the gas supply pipe 21 from a gas source 21a via a gas pipe. The gas pipe is provided with a flow rate controller 21b and an on-off valve 21c. Thus, the metal-containing catalyst gas from the gas source 21a is supplied into the processing container 1 via the gas pipe and gas supply pipe 21.

Herein, the gas source 21a supplies the metal-containing catalyst gas that forms a molecular layer including metal catalysts on a surface of the substrate W. Further, the metal-containing catalyst gas includes a gas containing a metal, a semimetal, or a compound thereof having Lewis acid property. Specifically, examples of the metal-containing catalyst gas may include organic, inorganic, or halide precursor gases containing Al, Co, Hf, Ni, Pt, Ru, W, Zr, Ti, B, Ga, In, Zn, Mg, or Ta. In addition, the metal catalyst may be a base that exposes Al, Co, Hf, Ni, Pt, Ru, W, Zr, Ti, B, Ga, In, Zn, Mg, or Ta. In the following description, the metal-containing catalyst gas will be described as a trimethylaluminum (TMA) gas.

The vertical portion (vertical portion where the gas holes 22g are formed) of the gas supply pipe (silicon precursor supplier) 22 is located inside the processing container 1. A silicon precursor gas is supplied to the gas supply pipe 22 from a gas source 22a via a gas pipe. The gas pipe is provided with a flow rate controller 22b and an on-off valve 22c. Thus, the silicon precursor gas from the gas source 22a is supplied into the processing container 1 via the gas pipe and gas supply pipe 22.

Herein, the gas source 22a supplies the silicon precursor gas containing silanol. Examples of the silicon precursor gas may include a tris(tert-pentoxy) silanol (TPSOL) gas, triethylsilanol, methylbis(tert-pentoxy) silanol, and tris(tert-butoxy) silanol. In the following description, the silicon precursor gas will be described as the tris(tert-pentoxy) silanol (TPSOL) gas.

The vertical portion (vertical portion where the gas holes 23g are formed) of the gas supply pipe (film formation suppression processing gas supplier) 23 is located in a plasma generation space to be described later. A film formation suppression processing gas is supplied to the gas supply pipe 23 from a gas source 23a via a gas pipe. The gas pipe is provided with a flow rate controller 23b and an on-off valve 23c. Thus, the film formation suppression processing gas from the gas source 23a is supplied to the plasma generation space via the gas pipe and gas supply pipe 23, where a plasma of the film formation suppression processing gas is formed, and active species of nitrogen (N) are supplied into the processing container 1.

Herein, the gas source 23a supplies the film formation suppression processing gas. The film formation suppression processing gas may be, for example, a nitrogen-containing gas. Examples of the nitrogen-containing gas may include a NH₃ gas, a H₂/N₂ gas (a mixed gas of a H₂ gas and a N₂ gas), and the like. In the following description, the nitrogen-containing gas will be described as a NH₃ gas.

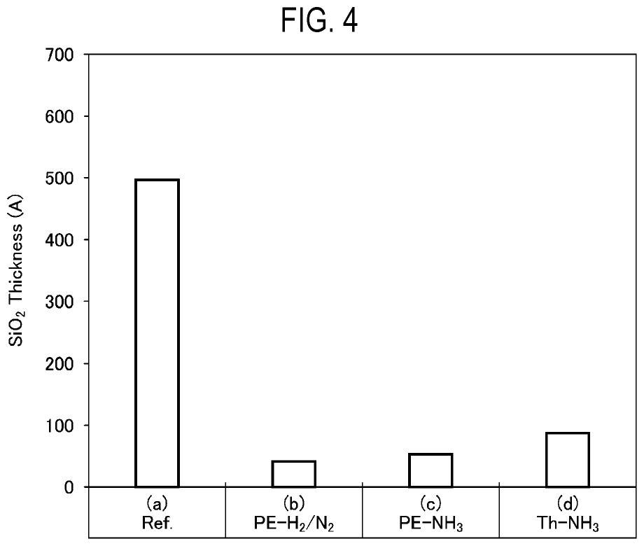

Further, the film formation suppression processing gas may be, for example, a hydrogen-containing gas. Examples of the hydrogen-containing gas may include gases containing at least hydrogen (H) or deuterium (D) such as a H₂ gas, a D₂ gas, a H₂O gas, a NH₃ gas, a silicon hydride gas, a PH₃ gas, a B₂H₆ gas, and a hydrocarbon gas. In (b) of FIG. 4 to be described below, a H₂ gas is used as the hydrogen-containing gas.

In addition, the substrate processing apparatus 100 has been described as a plasma processing apparatus configured to generate the plasma from the film formation suppression processing gas to supply the plasma to the substrate W inside the processing container 1, but the present disclosure is not limited thereto. The substrate processing apparatus 100 may also be a substrate processing apparatus configured to supply the film formation suppression processing gas from the gas supply pipe 23 to the substrate W, which is heated to a desired temperature, inside the processing container 1 to perform a thermal treatment on the substrate W.

A purge gas is supplied to the gas supply pipe 24 from a purge gas source (not illustrated) via a gas pipe. The gas pipe (not illustrated) is provided with a flow rate controller (not illustrated) and an on-off valve (not illustrated). Thus, the purge gas from the purge gas source is supplied into the processing container 1 via the gas pipe and gas supply pipe 24. The purge gas may be, for example, an inert gas such as argon (Ar) or nitrogen (N₂). In addition, the case where the purge gas is supplied from the purge gas source into the processing container 1 via the gas pipe and gas supply pipe 24 has been described, but the present disclosure is not limited thereto. The purge gas may be supplied from any of the gas supply pipes 21 to 23. A plasma generation mechanism 30 is formed on a part of the sidewall of the processing container 1. The plasma generation mechanism 30 forms the plasma from the film formation suppression processing gas to generate active species (e.g., ions and radicals) of the film formation suppression processing gas.

The plasma generation mechanism 30 includes a plasma partition wall 32, a pair of plasma electrodes 33 (one is illustrated in FIG. 1), a feeding line 34, a radio frequency power supply 35, and an insulation protective cover 36.

The plasma partition wall 32 is airtightly welded to an outer wall of the processing container 1. The plasma partition wall 32 is made of, for example, quartz. The plasma partition wall 32 has a concave cross-sectional shape, and covers an opening 31 formed at the sidewall of the processing container 1. The opening 31 is vertically elongated to cover all the substrates W, supported by the wafer boat 5, in the vertical direction. The gas supply pipe 23 configured to discharge the film formation suppression processing gas is positioned in the inner space, i.e., the plasma generation space, which is defined by the plasma partition wall 32 and communicates with an interior of the processing container 1.

A pair of plasma electrodes 33 (one is illustrated in FIG. 1) each have an elongated shape and are vertically arranged to face each other at outer surfaces of walls on both sides of the plasma partition wall 32. Each plasma electrode 33 is held, for example, by a holder (not illustrated) provided at the side surface of the plasma partition wall 32. The feeding line 34 is connected to a bottom of each plasma electrode 33.

The feeding line 34 electrically connects each plasma electrode 33 to the radio frequency power supply 35. In the illustrated example, the feeding line 34 is connected at one end thereof to the bottom of each plasma electrode 33 and at the other end thereof to the radio frequency power supply 35.

The radio frequency power supply 35 is connected to the bottom of each plasma electrode 33 via the feeding line 34, and supplies radio frequency power of, for example, 13.56 MHz to the pair of plasma electrodes 33. Thus, the radio frequency power is applied to the plasma generation space defined by the plasma partition wall 32. The plasma is formed from the film formation suppression processing gas discharged from the gas supply pipe 23 inside the plasma generation space to which the radio frequency power has been applied, and the resulting active species from the film formation suppression processing gas are then supplied to the interior of the processing container 1 via the opening 31.

The insulation protective cover 36 is provided outside the plasma partition wall 32 so as to cover that plasma partition wall 32. A coolant passage (not illustrated) is provided in an inner portion of the insulation protective cover 36, and the plasma electrodes 33 are cooled by flowing a coolant such as a cooled nitrogen (N₂) gas through the coolant passage. Further, a shield (not illustrated) may be provided between the plasma electrodes 33 and the insulation protective cover 36 so as to cover the plasma electrodes 33. The shield is made of, for example, a good conductor such as a metal, and is grounded.

An exhaust port 40 configured to vacuum-exhaust the interior of the processing container 1 is provided at a sidewall portion of the processing container 1 that faces the opening 31. The exhaust port 40 is vertically elongated to correspond to the wafer boat 5. An exhaust port cover member 41, which is molded to have a U-shaped cross-sectional shape, is provided at a portion of the processing container 1 corresponding to the exhaust port 40 so as to cover the exhaust port 40. The exhaust port cover member 41 extends upward along the sidewall of the processing container 1. An exhaust pipe 42 configured to exhaust the processing container 1 via the exhaust port 40 is connected to a lower portion of the exhaust port cover member 41. The exhaust pipe 42 is connected to a pressure control valve 43 configured to control an internal pressure of the processing container 1, and an exhaust device 44 including a vacuum pump and the like, such that the interior of the processing container 1 is exhausted by the exhaust device 44 via the exhaust pipe 42.

Further, a cylindrical heating mechanism 50 configured to heat the processing container 1 and the substrate W inside the processing container 1 is provided to surround the outer periphery of the processing container 1.

Further, the substrate processing apparatus 100 includes a controller 60. The controller 60 controls, for example, operations of various components of the substrate processing apparatus 100 such as the supply and stoppage of each gas by the opening and closing of the on-off valves 21c to 23c, the gas flow rate control by the flow rate controllers 21b to 23b, and the exhaust control by the exhaust device 44. Further, the controller 60 controls, for example, the on/off operation of radio frequency power supplied by the radio frequency power supply 35 and the temperature of the substrates W by the heating mechanism 50.

The controller 60 may be, for example, a computer or the like. Further, a computer program for executing operations of various components of the substrate processing apparatus 100 is stored in a storage medium. The storage medium may be, for example, a flexible disc, a compact disc, a hard disk, a flash memory, a DVD, or the like.

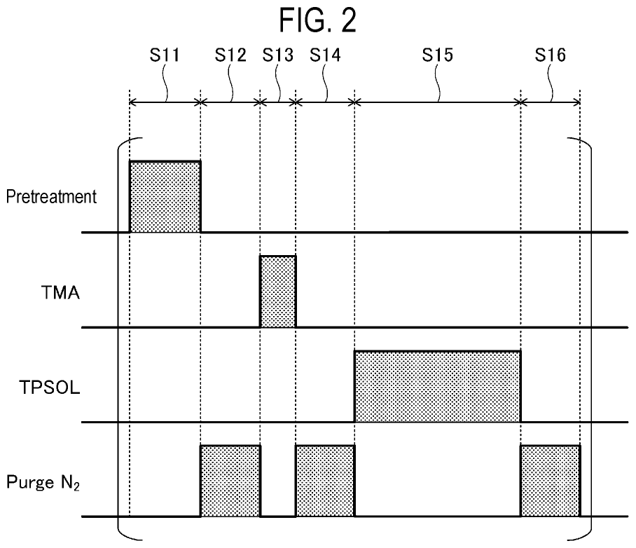

Next, an example of a film formation process by the substrate processing apparatus 100 will be described. FIG. 2 is a time chart illustrating an example of a film formation process according to the present embodiment. The film formation process according to the present embodiment forms, in a substrate W having a first surface and a second surface, a film containing at least silicon and oxygen on the second surface in a selective manner with respect to the first surface. Herein, an example of the film containing at least silicon (Si) and oxygen (O) includes a silicon oxide film (SiO₂ film) or a metal-containing SiO₂ film. The metal-containing SiO₂ film contains at least silicon (Si), oxygen (O), and metal atoms derived from a metal-containing catalyst gas to be described below. Herein, a case where a silicon oxide film is formed as the film containing at least silicon and oxygen will be described by way of example.

The film formation process according to the present embodiment as illustrated in FIG. 2 is a process of forming a silicon oxide film on the second surface of the substrate W by repeating a cycle a predetermined number of times, the cycle including a pretreatment step S11, a purging step S12, a step S13 of supplying a metal-containing catalyst gas (TMA gas), a purging step S14, a step S15 of supplying a silicon precursor gas (TPSOL gas), and a purging step S16. In addition, in FIG. 2, one cycle is illustrated in parentheses. Further, in steps S11 to S16, a N₂ gas as a purge gas may be constantly (continuously) supplied from the gas supply pipe 24 during the film formation process.

The pretreatment step S11 is a step of causing the first surface of the substrate W to be a nitrided surface made of a nitride. Specifically, in pretreatment step S11, the first surface of the substrate W undergoes nitridation. Herein, first, by opening the on-off valve 23c, a nitrogen-containing gas is supplied from the gas source 23a into the plasma partition wall 32 via the gas supply pipe 23. Further, radio frequency power (RF) is applied to the plasma electrodes 33 by the radio frequency power supply 35 to generate a plasma inside the plasma partition wall 32. Active species (ions and radicals) of nitrogen (N) generated by the plasma of the nitrogen-containing gas are supplied into the processing container 1 via the opening 31. By supplying the active species of nitrogen (N), the substrate W is nitrided, causing the first surface to be the nitrided surface made of the nitride. Thus, as described below, an amount of silicon oxide film formed on the first surface per cycle is suppressed.

In purging step S12, the excess nitrogen-containing gas and the like inside the processing container 1 are purged. In step S12, the on-off valve 23c is closed to stop the supply of the nitrogen-containing gas. Thus, the purge gas, which is constantly supplied from the gas supply pipe 24, purges the excess nitrogen-containing gas and the like inside the processing container 1. In addition, as illustrated in FIG. 2, a flow rate of the purge gas may be increased during the purging step S12.

In step S13 of supplying the metal-containing catalyst gas, the metal-containing catalyst gas (TMA gas) is supplied into the processing container 1. In step S13, first, by opening the on-off valve 21c, the metal-containing catalyst gas is supplied from the gas source 21a into the processing container 1 via the gas supply pipe 21. Thus, the metal-containing catalyst gas is adsorbed on the surface of the substrate W, forming a molecular layer containing metal catalysts.

In purging step S14, the excess metal-containing catalyst gas and the like inside the processing container 1 are purged. In step S14, the on-off valve 21c is closed to stop the supply of the metal-containing catalyst gas. Thus, the purge gas, which is constantly supplied from the gas supply pipe 24, purges the excess metal-containing catalyst gas and the like inside the processing container 1. In addition, as illustrated in FIG. 2, the flow rate of the purge gas may be increased during purging step S14.

In step S15 of supplying the silicon precursor gas, the silicon precursor gas (TPSOL gas) is supplied into the processing container 1. In step S15, first, by opening the on-off valve 22c, the silicon precursor gas is supplied from the gas source 22a into the processing container 1 via the gas supply pipe 22. Thus, the silicon precursor gas reacts with the metal catalyst on the surface of the substrate W, forming a silicon oxide film.

In purging step S16, the excess silicon precursor gas and the like inside the processing container 1 are purged. In step S16, the on-off valve 22c is closed to stop the supply of the silicon precursor gas. Thus, the purge gas, which is constantly supplied from the gas supply pipe 24, purges the excess silicon precursor gas and the like inside the processing container 1. In addition, as illustrated in FIG. 2, the flow rate of the purge gas may be increased during purging step S16.

By repeating the cycle described above, a silicon oxide film with a desired thickness is formed on the substrate W.

In addition, the pretreatment step S11 of supplying the nitrogen-containing gas, the step S13 of supplying the metal-containing catalyst gas (TMA gas), and the step S15 of supplying the silicon precursor gas (TPSOL gas) have been described as being performed sequentially (non-simultaneously), but the present disclosure is not limited thereto. Parts of the pretreatment step S11 of supplying the nitrogen-containing gas, the step S13 of supplying the metal-containing catalyst gas (TMA gas), and the step S15 of supplying the silicon precursor gas (TPSOL gas) may overlap.

Further, in the film formation process illustrated in FIG. 2, the pretreatment step S11 of supplying the nitrogen-containing gas has been described as a step in which RF power is applied to the plasma electrodes 33 to generate the active species of nitrogen (N) from the nitrogen-containing gas, and the generated active species of nitrogen (N) are supplied into the processing container 1, thereby performing a plasma treatment on the substrate W inside the processing container 1, but the present disclosure is not limited thereto. Alternatively, in pretreatment step S11 of supplying the nitrogen-containing gas, a nitrogen-containing gas (e.g., NH₃ gas) may be supplied from the gas supply pipe 23 to the substrate W heated to a desired temperature inside the processing container 1 to perform a thermal treatment on the substrate W. In this case, the RF power may not be applied.

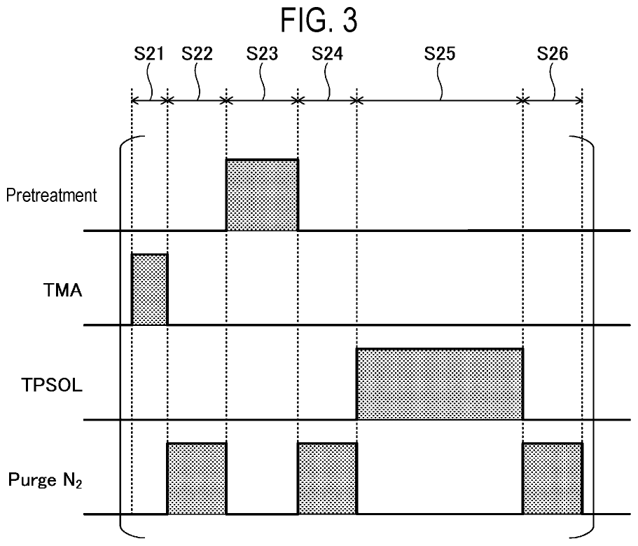

Next, another example of a film formation process by the substrate processing apparatus 100 will be described. FIG. 3 is a time chart illustrating another example of a film formation process according to the present embodiment. The film formation process according to the present embodiment forms, in the substrate W having a first surface and a second surface, a film containing at least silicon and oxygen on the second surface in a selective manner with respect to the first surface. Herein, a case where a silicon oxide film is formed as the film containing at least silicon and oxygen will be described by way of example.

The film formation process according to the present embodiment as illustrated in FIG. 3 is a process of forming a silicon oxide film on the second surface of the substrate W by performing a cycle a predetermined number of times, the cycle including a step S21 of supplying a metal-containing catalyst gas (TMA gas), a purging step S22, a pretreatment step S23, a purging step S24, a step S25 of supplying a silicon precursor gas (TPSOL gas), and a purging step S26. In addition, in FIG. 3, one cycle is illustrated in parentheses. Further, in steps S23 to S26, a N₂ gas as a purge gas may be constantly (continuously) supplied from the gas supply pipe 24 during the film formation process.

In step S21 of supplying the metal-containing catalyst gas, the metal-containing catalyst gas (TMA gas) is supplied into the processing container 1. In step S21, first, by opening the on-off valve 21c, the metal-containing catalyst gas is supplied from the gas source 21a into the processing container 1 via the gas supply pipe 21. Thus, the metal-containing catalyst gas is adsorbed on the surface of the substrate W, forming a molecular layer including metal catalysts.

In purging step S22, the excess metal-containing catalyst gas and the like inside the processing container 1 are purged. In step S22, the on-off valve 21c is closed to stop the supply of the metal-containing catalyst gas. Thus, the purge gas, which is constantly supplied from the gas supply pipe 24, purges the excess metal-containing catalyst gas and the like inside the processing container 1. In addition, as illustrated in FIG. 3, the flow rate of the purge gas may be increased during the purging step S22.

The pretreatment step S23 is a process of causing the first surface of the substrate W to be a nitrided surface made of a nitride. Specifically, in pretreatment step S23, the first surface of the substrate W is nitrided. Herein, first, by opening the on-off valve 23c, a nitrogen-containing gas is supplied from the gas source 23a into the plasma partition wall 32 via the gas supply pipe 23. Further, radio frequency power (RF) is applied to the plasma electrodes 33 by the radio frequency power supply 35 to generate a plasma inside the plasma partition wall 32. Active species (ions and radicals) of nitrogen (N) generated by the plasma of the nitrogen-containing gas are supplied into the processing container 1 via the opening 31. By supplying the active species of nitrogen (N), the substrate W is nitrided, causing the first surface to be the nitrided surface made of the nitride. Thus, as described below, an amount of silicon oxide film formed on the first surface per cycle is suppressed.

In purging step S24, the excess nitrogen-containing gas and the like inside the processing container 1 are purged. In step S24, the on-off valve 23c is closed to stop the supply of the nitrogen-containing gas. Thus, the purge gas, which is constantly supplied from the gas supply pipe 24, purges the excess nitrogen-containing gas and the like inside the processing container 1. In addition, as illustrated in FIG. 3, the flow rate of the purge gas may be increased during purging step S24.

In step S25 of supplying the silicon precursor gas, the silicon precursor gas (TPSOL gas) is supplied into the processing container 1. In step S25, first, by opening the on-off valve 22c, the silicon precursor gas is supplied from the gas source 22a into the processing container 1 via the gas supply pipe 22. Thus, the silicon precursor gas reacts with the metal catalyst on the surface of the substrate W, forming a silicon oxide film.

In purging step S26, the excess silicon precursor gas and the like inside the processing container 1 are purged. In step S26, the on-off valve 22c is closed to stop the supply of the silicon precursor gas. Thus, the purge gas, which is constantly supplied from the gas supply pipe 24, purges the excess silicon precursor gas and the like inside the processing container 1. In addition, as illustrated in FIG. 3, the flow rate of the purge gas may be increased during purging step S26.

By repeating the cycle described above, a silicon oxide film with a desired thickness is formed on the substrate W.

In addition, the pretreatment step S23 of supplying the nitrogen-containing gas, the step S21 of supplying the metal-containing catalyst gas (TMA gas), and the step S25 of supplying the silicon precursor gas (TPSOL gas) have been described as being performed sequentially (non-simultaneously), but the present disclosure is not limited thereto. Parts of the pretreatment step S23 of supplying the nitrogen-containing gas, the step S21 of supplying the metal-containing catalyst gas (TMA gas), and the step S25 of supplying the silicon precursor gas (TPSOL gas) may overlap.

In addition, in the film formation process illustrated in FIG. 3, the pretreatment step S23 of supplying the nitrogen-containing gas has been described as a step in which RF power is applied to the plasma electrodes 33 to generate active species of nitrogen (N) from the nitrogen-containing gas, and the generated active species of nitrogen (N) are supplied into the processing container 1, thereby performing a plasma treatment on the substrate W inside the processing container 1, but the present disclosure is not limited thereto. In pretreatment step S23 of supplying the nitrogen-containing gas, a nitrogen-containing gas (e.g., a NH₃ gas) may be supplied from the gas supply pipe 23 to the substrate W heated to a desired temperature inside the processing container 1 to perform a thermal treatment on the substrate W. In this case, the RF power may not be applied.

In addition, the pretreatment steps S11 and S23 have been described as steps of causing the first surface of the substrate W to be a nitrided surface made of a nitride, and specifically, steps of nitriding the first surface of the substrate W, but the present disclosure is not limited thereto.

The pretreatment steps S11 and S23 may be steps of causing the first surface of the substrate W to be a nitrided surface made of a nitride, and specifically, steps of forming a nitride film (silicon nitride film or SiN film) on the first surface of the substrate W, causing the first surface of the substrate W to be a nitrided surface made of a nitride. In such a configuration, in pretreatment steps S11 and S23, a precursor gas (a silicon-containing gas) and a nitrogen-containing gas are supplied into the processing container 1 to form a nitride film. For example, the precursor gas (a silicon-containing gas) and the nitrogen-containing gas may be simultaneously supplied into the processing container 1 to form a nitride film by a plasma chemical vapor deposition (CVD) method or a thermal CVD method. For example, the precursor gas (silicon-containing gas) and the nitrogen-containing gas may be alternately supplied into the processing container 1 to form a nitride film by a plasma atomic layer deposition (ALD) method or a thermal ALD method.

Further, in pretreatment steps S11 and S23, a carbon-containing film (carbon film) may be formed on the first surface of the substrate W, causing the first surface of the substrate W to be a carbonized surface made of a carbide. In such a configuration, in pretreatment steps S11 and S23, for example, a carbon-containing gas may be supplied into the processing container 1 to form a carbon-containing film (an organic film or a carbon film) on the substrate W.

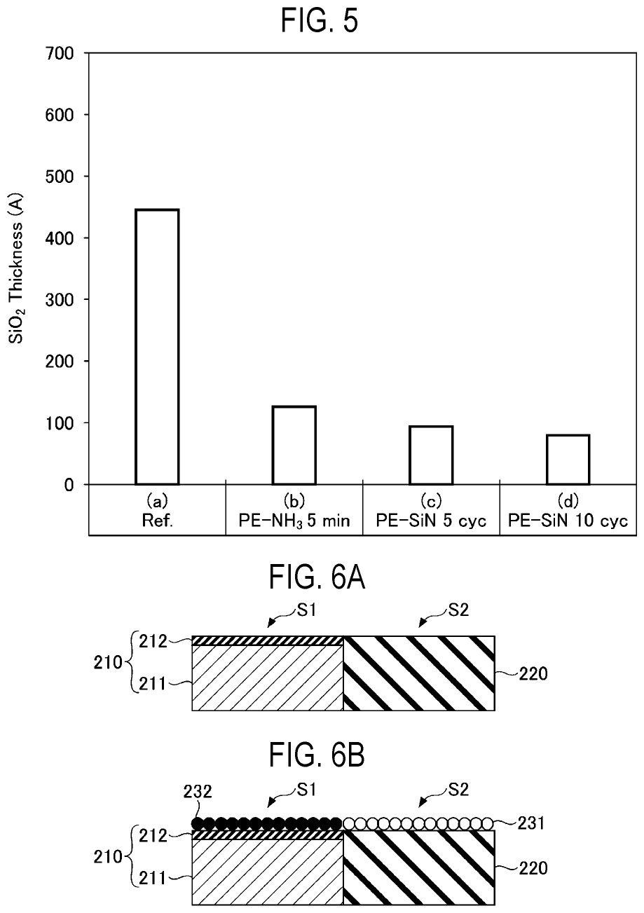

Herein, effects of performing the pretreatment step in the film formation process will be described with reference to FIGS. 4 and 5.

FIG. 4 illustrates an example of a graph illustrating results of an average film thickness in film formation processes. In FIG. 4, the average film thickness (thickness) of the silicon oxide film applied to the substrate W by respective film formation processes is illustrated as a bar graph.

(a) “Ref” represents the film formation results in a film formation process according to a reference example. A film formation process according to the reference example is a process of forming a silicon oxide film on the substrate W by performing an cycle a predetermined number of times, the cycle including the step S13 or S21 of supplying the metal-containing catalyst gas (TMA gas), the purging step S14 or S22, the step S15 or S25 of supplying the silicon precursor gas (TPSOL gas), and the purging step S16 or S26, and the pretreatment step S11 or S23 and the purging step S12 or S24 are omitted in this process.

(b) “PE-H₂/N₂” is a process of forming the silicon oxide film on the substrate W by the film formation process illustrated in FIG. 3. Further, in pretreatment step S23, a H₂/N₂ gas is used as the film formation suppression processing gas to perform a plasma treatment on the substrate W.

(c) “PE-NH₃” is a process of forming the silicon oxide film on the substrate W by the film formation process illustrated in FIG. 3. Further, in pretreatment step S23, a NH₃ gas is used as the film formation suppression processing gas (nitrogen-containing gas) to perform a plasma treatment on the substrate W.

(d) “Th-NH₃” is a process of forming the silicon oxide film on the substrate W by the film formation process illustrated in FIG. 3. Further, in pretreatment step S23, a NH₃ gas is used as the film formation suppression processing gas (nitrogen-containing gas) to perform a thermal treatment on the substrate W.

As illustrated in FIG. 4, when the surface of the substrate W on which the metal-containing catalyst gas having Lewis acid property is adsorbed, is subjected to nitridation in pretreatment step S23 (see (c) and (d) of FIG. 4), an amount of the formed silicon oxide film formed is reduced compared to the case where the pretreatment step S23 is not performed (see (a) of FIG. 4).

Further, as illustrated in (b) of FIG. 4, after the step S21 of supplying the metal-containing catalyst gas (TMA gas), the pretreatment step S23 using the hydrogen plasma is performed, and then step S25 of supplying the silicon precursor gas (TPSOL gas) are performed, such that the amount of the formed silicon oxide film is reduced compared to the case where the pretreatment step S23 is not performed (see (a) of FIG. 4).

FIG. 5 illustrates an example of a graph illustrating the results of an average film thickness in film formation processes. In FIG. 5, the average film thickness (thickness) of the silicon oxide film applied to the substrate W by the respective film formation processes is illustrated as a bar graph.

(a) “Ref” represents the film formation results in a film formation process according to a reference example. The film formation process according to the reference example is a process of forming a silicon oxide film on the substrate W by repeating a cycle a predetermined number of times, the cycle including the step S13 or S21 of supplying the metal-containing catalyst gas (TMA gas), the purging step S14 or S22, the step S15 or S25 of supplying the silicon precursor gas (TPSOL gas), and the purging step S16 or S26, and the pretreatment step S11 or S23 and the purging step S12 or S24 are omitted in this process.

(b) “PE-NH₃ 5 min” is a process of forming the silicon oxide film on the substrate W by the film formation process illustrated in FIG. 2. Further, in pretreatment step S11, a NH₃ gas is used as the nitrogen-containing gas to perform a plasma treatment on the substrate W for 5 minutes.

(c) “PE-SiN 5 cyc” is a process of forming the silicon oxide film on the substrate W by the film formation process illustrated in FIG. 2. Further, in pretreatment step S11, the SiN film is formed by repeating five ALD cycles by using a plasma ALD method.

(d) “PE-SiN 10 cyc” is a process of forming the silicon oxide film on the substrate W the film formation process illustrated in FIG. 2. Further, in pretreatment step S11, the SiN film is formed by repeating ten ALD cycles by using a plasma ALD method.

As illustrated in FIG. 5, when the surface of the substrate W becomes a nitrided surface (see (b) of FIG. 5) or a nitride film (see (c) and (d) of FIG. 5) by the pretreatment step S11, an amount of the formed silicon oxide film is reduced compared to the case where the pretreatment step S11 is not performed (see (a) of FIG. 5).

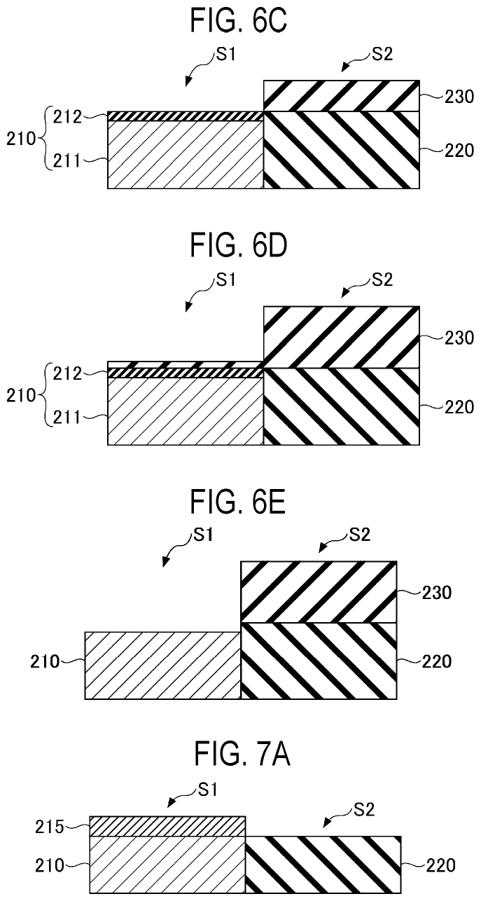

Next, examples of selective growth of a silicon oxide film will be described with reference to FIGS. 6A to 8E.

FIGS. 6A to 6E are schematic diagrams illustrating an example of selective growth of a silicon oxide film on a planar surface. The substrate W includes a first layer 210 having a first surface S1 and a second layer 220 having a second surface S2. The first layer 210 is formed, for example, of a metal-containing film (excluding oxide films) or a semiconductor film. The second layer 220 is formed, for example, of a metal oxide film or a silicon oxide film.

Herein, the film formation process illustrated in FIG. 2 will be described by way of example. In pretreatment step S11, the substrate W undergoes nitridation. As a result, as illustrated in FIG. 6A, only the first layer 210, which is likely to be nitrided, is nitrided. Thus, the first layer 210 includes a non-nitride layer 211 and a nitride layer 212. Further, the first surface S1 becomes a nitrided surface.

Subsequently, in step S13 of supplying the metal-containing catalyst gas, the metal-containing catalyst gas is adsorbed on the surface of the substrate W, forming a molecular layer containing metal catalysts. Herein, as illustrated in FIG. 6B, metal-containing catalysts 231 are adsorbed on the second surface S2. Further, metal-containing catalysts 232 are adsorbed on the first surface S1. Herein, the metal-containing catalysts 232 adsorbed on the first surface S1, which is a nitrided surface, exhibit reduced reactivity, as illustrated in (b) of FIG. 5.

Subsequently, in step S15 of supplying the silicon precursor gas, the silicon precursor gas reacts with the metal catalysts on the surface of the substrate W, forming a silicon oxide film. Herein, since the metal-containing catalysts 232 adsorbed on the first surface S1 exhibit reduced reactivity compared to the metal-containing catalysts 231 adsorbed on the second surface S2, a silicon precursor reacts more extensively with the metal catalysts on the second surface S2 than with the metal catalysts on the first surface S1. As a result, as illustrated in FIG. 6C, a silicon oxide film 230 is formed on the second surface S2 in a selective manner with respect to the first surface S1. Thus, by repeating the cycle of the film formation process illustrated in FIG. 2 (the pretreatment step S11, the step S13 of supplying the metal-containing catalyst gas, and the step S15 of supplying the silicon precursor gas), the silicon oxide film 230 is formed on the second surface S2 in a selective manner with respect to the first surface S1.

Further, by further repeating cycles of the film formation process, as illustrated in FIG. 6D, the silicon oxide film 230 is also formed on the first surface S1. Herein, the silicon oxide film 230 is formed to be thicker on the second surface S2 and thinner on the first surface S1.

In addition, in a case where the silicon oxide film 230 is also formed on the first surface S1, when further repeating cycles of the film formation process, the nitridation step (pretreatment step S11) may be omitted, and the step S13 of supplying the metal-containing catalyst gas and step S15 of supplying the silicon precursor gas may be repeated.

Further, the film formation process may include an etching step of etching the silicon oxide film 230 after the process illustrated in FIG. 2. Thus, the silicon oxide film 230 on the first layer 210 and the silicon oxide film 230 on the second layer 220 are etched, exposing the nitride layer 212 of the first layer 210. After the etching step, the film formation process may include an etching step of etching the nitride layer 212. Thus, as illustrated in FIG. 6E, in the substrate W having the first layer 210 and the second layer 220, the silicon oxide film 230 is selectively formed on the second layer 220. Further, in the film formation process, a cycle, which includes the process illustrated in FIG. 2, the etching step of etching the silicon oxide film 230 on the first layer 210, and the etching step of etching the nitride layer 212, may be repeated a predetermined number of times.

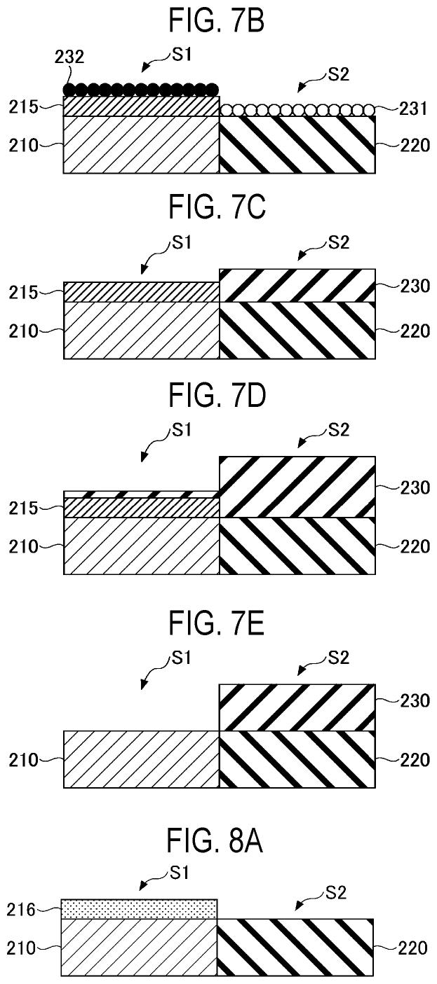

FIGS. 7A to 7E are schematic diagrams illustrating another example of the selective growth of a silicon oxide film on a planar surface. The substrate W includes the first layer 210 having the first surface S1 and the second layer 220 having the second surface S2. The first layer 210 is made of, for example, a metal-containing film (excluding oxide films) or a semiconductor film. The second layer 220 is made of, for example, a metal oxide film or a silicon oxide film.

Herein, the film formation process illustrated in FIG. 2 will be described by way of example. In pretreatment step S11, a nitride film 215 is formed on the substrate W. Herein, as illustrated in FIG. 7A, selective growth of a SiN film using an incubation time difference enables the selective formation of the nitride film 215 (SiN film) on the first layer 210. Thus, the first surface S1 becomes a nitrided surface.

Subsequently, in step S13 of supplying the metal-containing catalyst gas, the metal-containing catalyst gas is adsorbed on the surface of the substrate W, forming a molecular layer including metal catalysts. Herein, as illustrated in FIG. 7B, the metal-containing catalysts 231 are adsorbed on the second surface S2. Further, the metal-containing catalysts 232 are adsorbed on the first surface S1. Herein, the metal-containing catalysts 232 adsorbed on the first surface S1, which is a nitrided surface, exhibit reduced reactivity, as illustrated in (c) and (d) of FIG. 5.

Subsequently, in step S15 of supplying the silicon precursor gas, the silicon precursor gas reacts with the metal catalysts on the surface of the substrate W, forming a silicon oxide film. Herein, since the metal-containing catalysts 232 adsorbed on the first surface S1 exhibit reduced reactivity compared to the metal-containing catalysts 231 adsorbed on the second surface S2, the silicon precursor reacts more extensively with the metal catalysts on the second surface S2 than with the metal catalysts on the first surface S1. As a result, as illustrated in FIG. 7C, the silicon oxide film 230 is formed on the second surface S2 in a selective manner with respect to the first surface S1. Thus, by repeating the cycle of the film formation process illustrated in FIG. 2 (the pretreatment step S11, the step S13 of supplying the metal-containing catalyst gas, and the step S15 of supplying the silicon precursor gas), the silicon oxide film 230 is formed on the second surface S2 in a selective manner with respect to the first surface S1. In addition, after the nitride film 215 has been formed on the first surface S1, the film formation of the nitride film 215 (pretreatment step S11) may be omitted, and the step S13 of supplying the metal-containing catalyst gas and the step S15 of supplying the silicon precursor gas may be repeated.

Further, by further repeating cycles of the film formation process, as illustrated in FIG. 7D, the silicon oxide film 230 is also formed on the first surface S1. Herein, the silicon oxide film 230 is formed thicker on the second surface S2 and thinner on the first surface S1.

In addition, in a case where the silicon oxide film 230 is also formed on the first surface S1, when further repeating cycles of the film formation process, the film formation of the nitride film 215 (pretreatment step S11) may be omitted, and the step S13 of supplying the metal-containing catalyst gas and step S15 of supplying the silicon precursor gas may be repeated.

Further, the film formation process may include an etching step of etching the silicon oxide film 230 after the process illustrated in FIG. 2. Thus, the silicon oxide film 230 on the first layer 210 and the silicon oxide film 230 on the second layer 220 are etched, exposing the nitride film 215 of the first layer 210. After the etching step, the film formation process may include an etching step of etching the nitride film 215. Thus, as illustrated in FIG. 7E, in the substrate W having the first layer 210 and the second layer 220, the silicon oxide film 230 is selectively formed on the second layer 220. Further, in the film formation process, a cycle, which includes the process illustrated in FIG. 2, the etching step of the silicon oxide film 230 on the first layer 210, and the etching step of etching the nitride film 215, may be repeated a predetermined number of times.

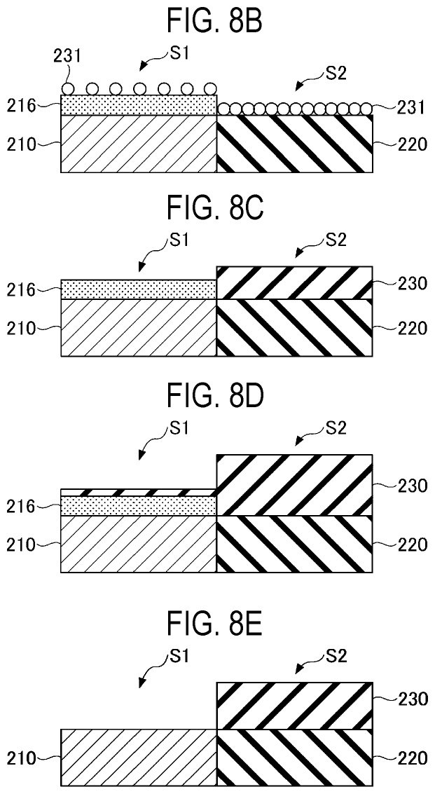

FIGS. 8A to 8E are schematic diagrams illustrating a further example of the selective growth of a silicon oxide film on a planar surface. The substrate W includes the first layer 210 having the first surface S1 and the second layer 220 having the second surface S2. The first layer 210 is made of, for example, a metal-containing film (excluding oxide films) or a semiconductor film. The second layer 220 is made of, for example, a metal oxide film or a silicon oxide film.

Herein, the film formation process illustrated in FIG. 2 will be described by way of example. In pretreatment step S11, a carbon-containing film 216 is formed on the substrate W. Herein, as illustrated in FIG. 8A, the selective growth of a carbon-containing film using an incubation time difference enables the selective formation of the carbon-containing film 216 on the first layer 210. Thus, the first surface S1 becomes a carbonized surface.

Subsequently, in step S13 of supplying the metal-containing catalyst gas, the metal-containing catalyst gas is adsorbed on the surface of the substrate W, forming a molecular layer containing metal catalysts. Herein, as illustrated in FIG. 8B, the metal-containing catalysts 231 are adsorbed on the second surface S2. Further, the metal-containing catalysts 231 are adsorbed on the first surface S1. Herein, the number of metal-containing catalysts 231 adsorbed per unit area on the first surface S1, which is a carbonized surface, is smaller compared to the number of metal-containing catalysts 231 adsorbed per unit area on the second surface S2.

Subsequently, in step S15 of supplying the silicon precursor gas, the silicon precursor gas reacts with the metal catalysts on the surface of the substrate W, forming a silicon oxide film. Herein, the number of metal-containing catalysts 231 adsorbed on the first surface S1 is smaller than the number of metal-containing catalysts 231 adsorbed on the second surface S2, and the silicon precursor reacts more extensively with the metal catalysts on the second surface S2 than with the metal catalysts on the first surface S1. As a result, as illustrated in FIG. 8C, the silicon oxide film 230 is formed on the second surface S2 in a selective manner with respect to the first surface S1. Thus, by repeating the cycle of the film formation process illustrated in FIG. 2 (the pretreatment step S11, the step S13 of supplying the metal-containing catalyst gas, and the step S15 of supplying the silicon precursor gas), the silicon oxide film 230 is formed on the second surface S2 in a selective manner with respect to the first surface S1. In addition, after the carbon-containing film 216 is formed on the first surface S1, the film formation of the carbon-containing film 216 (pretreatment step S11) may be omitted, and the step S13 of supplying the metal-containing catalyst gas and step S15 of supplying the silicon precursor gas may be repeated.

Further, by further repeating cycles of the film formation process, as illustrated in FIG. 8D, the silicon oxide film 230 is also formed on the first surface S1. Herein, the silicon oxide film 230 is formed thicker on the second surface S2 and thinner on the first surface S1.

In addition, in a case where the silicon oxide film 230 is also formed on the first surface S1, when further repeating cycles of the film formation process, the film formation of the carbon-containing film 216 (pretreatment step S11) may be omitted, and the step S13 of supplying the metal-containing catalyst gas and the step S15 of supplying the silicon precursor gas may be repeated.

Further, after the process illustrated in FIG. 2, the film formation process may include an etching step of etching the silicon oxide film 230. Thus, the silicon oxide film 230 on the first layer 210 and the silicon oxide film 230 on the second layer 220 are etched, exposing the carbon-containing film 216 of the first layer 210. Then, after the etching step, the film formation process may include an etching step of etching the carbon-containing film 216. Thus, as illustrated in FIG. 8E, in the substrate W having the first layer 210 and the second layer 220, the silicon oxide film 230 is selectively formed on the second layer 220. Further, in the film formation process, a cycle, which includes the process illustrated in FIG. 2, the etching step of etching the silicon oxide film 230 on the first layer 210, and the etching step of etching the carbon-containing film 216, may be repeated a predetermined number of times.

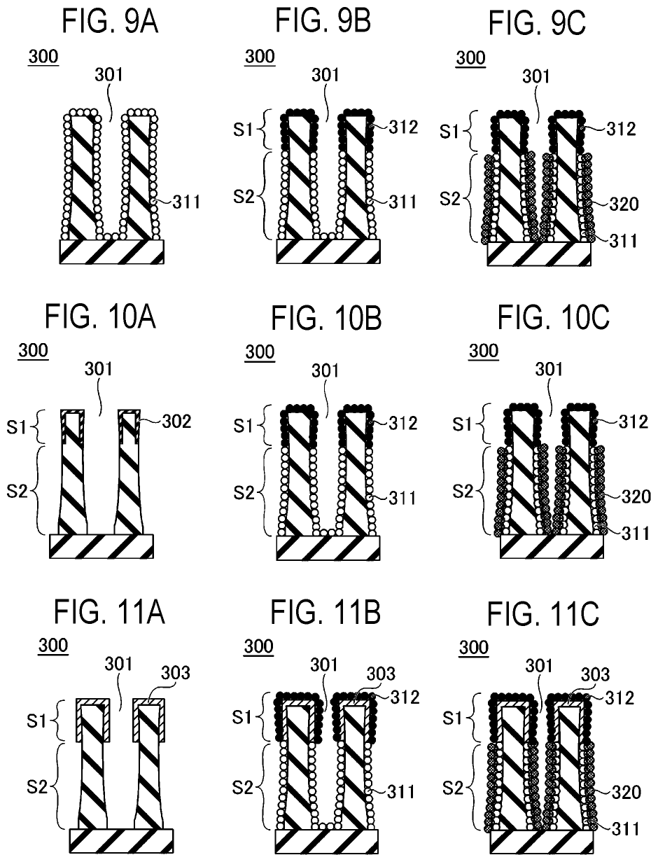

Next, other examples of selective growth of a silicon oxide film in a three-dimensional shape will be described with reference to FIGS. 9A to 11C.

FIGS. 9A to 9C are schematic diagrams illustrating an example of the selective growth of a silicon oxide film in a three-dimensional shape. The substrate W has an uneven structure 300 formed with a recess 301 such as a trench.

Herein, the film formation process illustrated in FIG. 3 will be described by way of example. In step S21 of supplying the metal-containing catalyst gas, the metal-containing catalyst gas is adsorbed on the surface of the substrate W, forming a molecular layer containing metal catalysts. Herein, as illustrated in FIG. 9A, metal-containing catalysts 311 are adsorbed on the entire surface of the recess 301.

Subsequently, in pretreatment step S23, only an upper portion of the recess 301 is subjected to nitridation. As illustrated in FIG. 9B, a surface of the nitrided upper portion is referred to as the first surface S1, while a surface of a non-nitrided lower portion of the recess 301 is referred to as the second surface S2. Thus, metal-containing catalysts 312 on the first surface S1 exhibit reduced reactivity, as illustrated in (c) and (d) of FIG. 4.

Subsequently, in step S25 of supplying the silicon precursor gas, the silicon precursor gas reacts with the metal catalysts on the surface of the substrate W, forming a silicon oxide film. Herein, since the metal-containing catalysts 312 adsorbed on the first surface S1 exhibit reduced reactivity compared to the metal-containing catalysts 311 adsorbed on the second surface S2, silicon precursors 320 react more extensively with the metal catalysts on the second surface S2 than with the metal catalysts on the first surface S1, as illustrated in FIG. 9C. As a result, film formation is performed on the second surface S2 in a selective manner with respect to the first surface S1. Thus, by repeating the cycle of the film formation process illustrated in FIG. 3 (the step S21 of supplying the metal-containing catalyst gas, the pretreatment step S23, and the step S25 of supplying the silicon precursor gas), the silicon oxide film is formed on the second surface S2 in a selective manner with respect to the first surface S1.

A further description with reference to FIGS. 9A to 9C will be provided. Herein, the film formation process illustrated in FIG. 3 will be described by way of example. In step S21 of supplying the metal-containing catalyst gas, the metal-containing catalyst gas is adsorbed on the surface of the substrate W, forming a molecular layer containing metal catalysts. Herein, as illustrated in FIG. 9A, the metal-containing catalysts 311 are adsorbed on the entire surface of the recess 301.

Subsequently, in pretreatment step S23, only an upper portion of the recess 301 is treated with a hydrogen plasma (plasma of a H₂/N₂ mixed gas). As illustrated in FIG. 9B, a surface of the upper portion treated with the hydrogen plasma (plasma of the H₂/N₂ mixed gas) is referred to as the first surface S1, while a surface of a lower portion of the recess 301 not treated with the hydrogen plasma (plasma of the H₂/N₂ mixed gas) is referred to as the second surface S2. As a result, the metal-containing catalysts 312 on the first surface S1, exposed to the hydrogen plasma (plasma of the H₂/N₂ mixed gas), exhibit reduced reactivity, as illustrated in (b) of FIG. 4. Meanwhile, the metal-containing catalysts 311 on the second surface S2, which is not exposed to the hydrogen plasma (plasma of the H₂/N₂ mixed gas), maintain reactivity, as illustrated in (a) of FIG. 4.

Subsequently, in step S25 of supplying the silicon precursor gas, the silicon precursor gas reacts with the metal catalysts on the surface of the substrate W, forming a silicon oxide film. Herein, since the metal-containing catalysts 312 adsorbed on the first surface S1 exhibit reduced reactivity compared to the metal-containing catalysts 311 adsorbed on the second surface S2, the silicon precursors 320 react more extensively with the metal catalysts on the second surface S2 than with the metal catalysts on the first surface S1, as illustrated in FIG. 9C. As a result, film formation is performed on the second surface S2 in a selective manner with respect to the first surface S1. Thus, by repeating the cycle of the film formation process illustrated in FIG. 3 (the step S21 of supplying the metal-containing catalyst gas, pretreatment step S23, and step S25 of supplying the silicon precursor gas), the silicon oxide film is formed on the second surface S2 in a selective manner with respect to the first surface S1.

Further, by further repeating cycles of the film formation process, the silicon oxide film is also formed on the first surface S1. Herein, the silicon oxide film is formed thicker on the second surface S2 and thinner on the first surface S1.

In addition, in a case where the silicon oxide film is also formed on the first surface S1, when further repeating cycles of the film formation process, the step of performing nitridation or hydrogen plasma treatment only on the upper portion of the recess 301 (pretreatment step S11) may be omitted, and the step S21 of supplying the metal-containing catalyst gas and the step S25 of supplying the silicon precursor gas may be repeated.

FIGS. 10A to 10C are schematic diagrams illustrating another example of selective growth of a silicon oxide film in a three-dimensional shape. The substrate W has an uneven structure 300 formed with the recess 301 such as a trench.

Herein, the film formation process illustrated in FIG. 2 will be described by way of example. In pretreatment step S11, only an upper portion of the recess 301 is subjected to nitridation to form a nitride layer 302. A surface of the nitrided upper portion is referred to as the first surface S1, while a surface of a non-nitrided lower portion of the recess 301 is referred to as the second surface S2. Thus, as illustrated in FIG. 10A, the first surface S1 is nitrided. In other words, the first surface S1 becomes a nitrided surface.

Subsequently, in step S13 of supplying the metal-containing catalyst gas, the metal-containing catalyst gas is adsorbed on the surface of the substrate W, forming a molecular layer including metal catalysts. Herein, as illustrated in FIG. 10B, the metal-containing catalysts 311 are adsorbed on the second surface S2. Further, the metal-containing catalysts 312 are adsorbed on the first surface S1. Herein, the metal-containing catalysts 312 adsorbed on the first surface S1, which is a nitrided surface, exhibit reduced reactivity, as illustrated in (b) of FIG. 5.

Subsequently, in step S15 of supplying the silicon precursor gas, the silicon precursor gas reacts with the metal catalysts on the surface of the substrate W, forming a silicon oxide film. Herein, since the metal-containing catalysts 312 adsorbed on the first surface S1 exhibit reduced reactivity compared to the metal-containing catalysts 311 adsorbed on the second surface S2, the silicon precursors 320 react more extensively with the metal catalysts on the second surface S2 than with the metal catalysts on the first surface S1, as illustrated in FIG. 10C. As a result, film formation is performed on the second surface S2 in a selective manner with respect to the first surface S1. Thus, by repeating the cycle of the film formation process illustrated in FIG. 2 (the pretreatment step S11, the step S13 of supplying the metal-containing catalyst gas, and the step S15 of supplying the silicon precursor gas), the silicon oxide film is formed on the second surface S2 in a selective manner with respect to the first surface S1.

Further, by further repeating cycles of the film formation process, the silicon oxide film is also formed on the first surface S1. Herein, the silicon oxide film is formed thicker on the second surface S2 and thinner on the first surface S1.

In addition, in a case where the silicon oxide film is also formed on the first surface S1, when further repeating cycles of the film formation process, the nitridation step (pretreatment step S11) may be omitted, and the step S13 of supplying the metal-containing catalyst gas and the step S15 of supplying the silicon precursor gas may be repeated.

FIGS. 11A to 11C are schematic diagrams illustrating another example of selective growth of a silicon oxide film in a three-dimensional shape. The substrate W has an uneven structure 300 formed with the recess 301 such as a trench.

Herein, the film formation process illustrated in FIG. 2 will be described by way of example. In pretreatment step S11, a nitride film 303 is formed only an upper portion of the recess 301. A surface of the upper portion, where the nitride film 303 is formed, is referred to as the first surface S1, while a surface of a lower portion of the recess 301, where the nitride film 303 is not formed, is referred to as the second surface S2. Thus, as illustrated in FIG. 11A, the first surface S1 becomes a nitrided surface.

Subsequently, in step S13 of supplying the metal-containing catalyst gas, the metal-containing catalyst gas is adsorbed on the surface of the substrate W, forming a molecular layer containing metal catalysts. Herein, as illustrated in FIG. 11B, the metal-containing catalysts 311 are adsorbed on the second surface S2. Further, the metal-containing catalysts 312 are adsorbed on the first surface S1. Herein, the metal-containing catalysts 312 adsorbed on the first surface S1, which is a nitrided surface, exhibit reduced reactivity, as illustrated in (c) and (d) of FIG. 5.

Subsequently, in step S15 of supplying the silicon precursor gas, the silicon precursor gas reacts with the metal catalysts on the surface of the substrate W, forming a silicon oxide film. Herein, since the metal-containing catalysts 312 adsorbed on the first surface S1 exhibit reduced reactivity compared to the metal-containing catalysts 311 adsorbed on the second surface S2, the silicon precursors 320 react more extensively with the metal catalysts on the second surface S2 than with the metal catalysts on the first surface S1, as illustrated in FIG. 11C. As a result, film formation is performed on the second surface S2 in a selective manner with respect to the first surface S1. Thus, by repeating the cycle of the film formation process illustrated in FIG. 2 (the pretreatment step S11, the step S13 of supplying the metal-containing catalyst gas, and the step S15 of supplying the silicon precursor gas), a silicon oxide film is formed on the second surface S2 in a selective manner with respect to the first surface S1. In addition, after the nitride film 303 is formed on the first surface S1, the film formation of the nitride film 303 (pretreatment step S11) may be omitted, and the step S13 of supplying the metal-containing catalyst gas and the step S15 of supplying the silicon precursor gas may be repeated.

Further, by further repeating cycles of the film formation process, the silicon oxide film is also formed on the first surface S1. Herein, the silicon oxide film is formed thicker on the second surface S2 and thinner on the first surface S1.

In addition, in a case where the silicon oxide film is also formed on the first surface S1, when further repeating cycles of the film formation process, the film formation of the nitride film 303 (pretreatment step S11) may be omitted, and the step S13 of supplying the metal-containing catalyst gas and the step S15 of supplying the silicon precursor gas may be repeated.

In addition, the example illustrated in FIGS. 11A to 11C has described that the nitride film 303 is formed on the upper portion of the recess 301, but the present disclosure is not limited thereto, and a carbon-containing film may be formed. Further, in the example illustrated in FIGS. 11A to 11C, the nitride film 303 is formed on the upper portion of the recess 301, but the nitride film 303 may be formed on the lower portion of the recess 301.

Although the film formation method of the present embodiment using the substrate processing apparatus 100 has been described above, the present disclosure is not limited to the above-described embodiment, and various modifications and improvements are possible within the scope of the gist of the present disclosure described in the claims.

In addition, the substrate processing apparatus 100 configured to perform the film formation process has been described as a vertical substrate processing apparatus configured to process the multiple substrates W placed in multiple stages as illustrated in FIG. 1, but the present disclosure is not limited thereto. The substrate processing apparatus 100 may also be a single-wafer type substrate processing apparatus or a semi-batch type substrate processing apparatus. Further, the above-described film formation process may be applied to a single-wafer type substrate processing apparatus in which a single substrate is placed and processed on a stage. Further, the above-described film formation process may also be applied to a semi-batch type substrate processing apparatus in which multiple substrates are placed and processed on a stage.

According to an embodiment of the present disclosure, it is possible to provide a film formation method and a substrate processing apparatus of selectively forming a film containing at least silicon and oxygen.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film formation method of forming, in a substrate having a first surface and a second surface, a film containing at least silicon and oxygen on the second surface in a selective manner with respect to the first surface, the film formation method comprising:
causing the first surface to be a nitrided surface made of nitride or a carbonized surface made of carbide by supplying a nitrogen-containing gas or a carbon-containing gas to the substrate;
supplying a metal-containing catalyst to the substrate; and
supplying a silicon precursor including silanol to the substrate.

2. The film formation method of claim 1, wherein the first surface is a metal-containing film excluding a metal oxide film, or a semiconductor film, and
wherein the second surface is a metal oxide film or a silicon oxide film.

3. The film formation method of claim 1, wherein the first surface is an upper portion of a recess, and
wherein the second surface is a lower portion of the recess.

4. The film formation method of claim 1, wherein the causing the first surface to be the nitrided surface or the carbonized surface includes supplying the nitrogen-containing gas to the substrate to nitride the first surface.

5. The film formation method of claim 1, wherein the causing the first surface to be the nitrided surface or the carbonized surface includes supplying the nitrogen-containing gas to the substrate to form a nitride film on the first surface.

6. The film formation method of claim 1, wherein the causing the first surface to be the nitrided surface or the carbonized surface includes supplying the carbon-containing gas to the substrate to form a carbon-containing film on the first surface.

7. The film formation method of claim 1, wherein the causing the first surface to be the nitrided surface or the carbonized surface, the supplying the metal-containing catalyst, and the supplying the silicon precursor are performed in this order.

8. The film formation method of claim 1, wherein the supplying the metal-containing catalyst, the causing the first surface to be the nitrided surface or the carbonized surface, and the supplying the silicon precursor are performed in this order.

9. The film formation method of claim 1, wherein the supplying the metal-containing catalyst, the causing the first surface to be the nitrided surface or the carbonized surface, and the supplying the silicon precursor are repeated a plurality of times.

10. The film formation method of claim 1, further comprising etching the first surface and the film containing at least silicon and oxygen formed on the second surface, after the supplying the silicon precursor.

11. The film formation method of claim 1, wherein the metal-containing catalyst includes a metal, a semimetal, or a compound thereof having a Lewis acid property.

12. The film formation method of claim 1, wherein a metal contained in the metal-containing catalyst includes at least one selected from the group of Al, Co, Hf, Ni, Pt, Ru, W, Zr, Ti, B, Ga, In, Zn, Mg, and Ta.

13. A film formation method of forming, in a substrate having a first surface and a second surface, a film containing at least silicon and oxygen on the second surface in a selective manner with respect to the first surface, the film formation method comprising:
supplying a metal-containing catalyst to the substrate;
supplying a hydrogen-containing gas to the substrate to treat the first surface, after supplying the metal-containing catalyst; and
supplying a silicon precursor including silanol to the substrate.

14. A substrate processing apparatus comprising:
a processing container configured to accommodate a substrate therein;
a metal-containing catalyst supplier configured to supply a metal-containing catalyst into the processing container;
a silicon precursor supplier configured to supply a silicon precursor including silanol into the processing container;
a film formation suppression processing gas supplier configured to supply a film formation suppression processing gas into the processing container; and
a controller,
wherein the controller is configured to execute a process on the substrate having a first surface and a second surface, the process comprising:
causing the first surface to be a nitrided surface made of a nitride or a carbonized surface made of carbide by supplying, as the film formation suppression processing gas, a nitrogen-containing gas or a carbon-containing gas to the substrate;
supplying the metal-containing catalyst to the substrate; and
supplying the silicon precursor including silanol to the substrate.
